(19) United States
(12) Patent Application Publication
(10) Pub. No.: US 2008/0265373 A1
(43) Pub. Date: Oct. 30, 2008

(54) SEMICONDUCTOR DEVICE

(76) Inventors: Toshiya Nozawa, Tokyo (JP); Ryo Niide, Tokyo (JP); Itaru Iijima, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 12/107,620

(22) Filed: Apr. 22, 2008

(30) Foreign Application Priority Data
Apr. 24, 2007 (JP) 2007-114280

(51) Int. Cl. H01L 29/93

(52) U.S. Cl. 257/595; 257/E27.024

(57) ABSTRACT

An epitaxial layer is formed in a main surface of a semiconductor substrate of a first conductivity type. The epitaxial layer is partitioned into a first area and a second area by a device isolation area. A PN junction portion, which has a semiconductor layer of a second conductivity type and configures a variable capacitance element, is provided at the surface of the epitaxial layer of the first area. A PN junction portion, which has a semiconductor layer of the second conductivity type whose low portion is formed closer to the semiconductor substrate than the semiconductor layer of the second conductivity type configuring the above variable capacitive PN junction and which is configured as a fixed capacitance, is provided at the surface of the epitaxial layer of the second area.

### CROSS-REFERENCE TO RELATED APPLICATIONS

The disclosure of Japanese Patent Application No. 2007-114280 filed on Apr. 24, 2007 including the specification, drawings and abstract is incorporated herein by reference in its entirety.

### BACKGROUND OF THE INVENTION

The present invention relates to a semiconductor device, and to, for example, a technique effective when applied to a variable capacitance diode used in an antenna circuit or the like.

Japanese Unexamined Patent Publication No. 2006-319477 has been known as an example of a decoding antenna employed in a portable radio device and a mobile radio device corresponding to a cellular phone band and a digital TV (television) band. The same publication discloses that two variable capacitance diodes are coupled in series with a reverse polarity thereby to obtain a large change in capacitance at a low voltage.

### SUMMARY OF THE INVENTION

In the variable capacitance diode, the capacitance at a given specific voltage has been normalized while a terminal-to-terminal capacitance C changes depending on a reverse voltage applied thereto. Capacitance values at a plurality of applied voltages on the low-voltage and high-voltages sides are ordinarily normalized, and one obtained by dividing the capacitance value on the low-voltage side by the capacitance value on the high-voltage side is called “capacitance change ratio”. Simulation results obtained where the variable capacitance diode is brought to a low capacitance as it is while the capacitance change ratio is being maintained, are shown in FIGS. 8 and 9. Here, an equivalent series resistance Rs is represented by the following approximate expression (1). As to this simulation, when S (junction area) is set to half, a capacitance value C assumes ¼ as shown in FIG. 8, whereas the equivalent series resistance Rs becomes four times or more as shown in FIG. 9.

Rs=ρepi(depi/S)+ρsub(dsub/S)+Rc (1)

where ρepi and ρsub respectively indicate the resistivities of an epi layer and a substrate, dsub indicates the thickness of the substrate, depi indicates the thickness (one obtained by excepting the thickness of a p region and the thickness of a depletion layer from the thickness of the epi layer) of an executive epi layer, Rc indicates the contact resistance between an AL (aluminum) electrode and a gold electrode, and silicon, and S indicates the area of a pn junction, respectively.

A variable capacitance diode for a digital TV tuner is used when it makes use of such a characteristic that the capacitance changed according to the application of a voltage thereto, and tuned to a radio wave (frequency allocated to each channel) that one desires to receive. Digital terrestrial broadcasing (so-called one-segment broadcasting) for mobile terminals has been started from April in 2006. Through mobile devices such as a cellular phone and an in-vehicle TV, watching of programs of one-segment broadcasting can be realized. In terms of power consumption (viewing time), measurements or support taken for a range at a low voltage (less than or equal to 3V) has been required for these TV tuner products corresponding to one-segment broadcasting capable of being watched by a portable device. While first generation models are now on sale from cell phone makers, bar-shaped antennas, which are used by stretching them from their main bodies, have been adopted to all. However, antenna building-in is in the mainstream in terms of the design characteristics of the mobile device. There has been a strong demand for built-in antennas even at the one-segment broadcasting.

It is thought that in order to efficiently receive a wide range of frequency band for one-segment broadcasting with the above building-in of the antenna, a high capacitance change ratio in a range of a low voltage (about 0V to 3V) will be required for a variable capacitance diode for a tunable antenna, which adapts to a change of a resonant wavelength. On the other hand, the variable capacitance diode needs to have a high Q value (selectivity) to enhance the selectivity of a tuning circuit and prevent a reduction in gain. This Q value is given by the following approximate expression (2). While the Q value changes depending on the frequency f as is apparent from the equation (2), it can be represented as a quantity irrelevant to the frequency f where the Q value is represented by an equivalent series resistance Rs.

Q=1/(2π·f·Ct·Rs) (2)

where f indicates the frequency, Ct indicates a capacitance value, and Rs indicates the equivalent series resistance. Thus, while there is a need to hold a low capacitance and reduce Rs in order to enhance the Q value, the Q value has a trade-off relationship with a capacitance change ratio. Although the related art of the patent document 1 satisfies the condition that the large change in capacitance can be obtained at the low voltage as mentioned above, it has the following problems. Firstly, there is a need to use two variable capacitance elements and the number of parts increases. Secondly, since the two variable capacitance elements are coupled in a series configuration, the capacitance value can be reduced to ½, whereas the equivalent series resistance Rs is increased twice, thereby reducing the Q value. This involves a problem similar to a case in which a junction area S is reduced to lessen the capacitance value C as shown in FIGS. 8 and 9. This therefore led to the creation of the present invention to obtain a semiconductor device capable of maintaining a large capacitance change ratio while being held at a low Ct and a low Rs.

An object of the present invention is to provide a semiconductor device that has realized a large capacitance change ratio while being held at a low capacitance and a low resistance. The above and other objects and novel features of the present invention will become more completely apparent from the description of the present specification and the accompanying drawings.

One embodiment according to the present application is as follows: A first semiconductor layer of a first conductivity type having an impurity concentration lower than a semiconductor substrate is formed over the semiconductor substrate. A second semiconductor layer of the first conductivity type having an impurity concentration higher than the first semiconductor layer is formed in a first area of a main surface of the first semiconductor layer. A third semiconductor layer having a second conductivity type opposite to the first conductivity type is formed in a surface of the second semiconductor layer. A first electrode is formed over the third semiconductor layer and electrically coupled to the third semiconductor layer. A fourth semiconductor layer having the second conductivity type is formed in a second area of the main surface of the first semiconductor layer, which is different from the first area. A second electrode electrically coupled to the fourth semiconductor layer is formed over the fourth semiconductor layer. A third electrode electrically coupled to the semiconductor substrate is formed at a back surface of the semiconductor substrate. A diode element including a PN junction formed by the second semiconductor layer and the third semiconductor layer is configured. A capacitive element including the first semiconductor layer, the semiconductor substrate and the fourth semiconductor layer in the second area is formed. A variable filter circuit is configured in which the third electrode is coupled to a control voltage terminal, the first and second electrodes are respectively coupled to a first signal terminal and a second signal terminal, and the capacitance of the diode element is controlled by a voltage applied to the control voltage terminal. A bottom portion of the fourth semiconductor layer is formed at a position closer to the semiconductor substrate than a low portion of the third semiconductor layer.

A variable capacitance portion and a capacitance portion that substantially acts as a fixed capacitance are provided on one semiconductor substrate. A capacitance value can be reduced by a series circuit that uses a semiconductor substrate in common. Further, a bottom portion of the fourth semiconductor layer is formed at a position closer to the semiconductor substrate than a low portion of the third semiconductor layer, thereby reducing a resistive component at a first semiconductor layer (epitaxial layer) of a low concentration, whereby an increase in Rs at the series circuit can be prevented.

### BRIEF DESCRIPTION OF THE DRAWINGS

FIGS. 1A and 1B are configuration diagrams showing one embodiment of a semiconductor chip that configures a variable capacitance diode according to the present invention;

FIGS. 2A and 2B is a configuration diagram illustrating one embodiment of a semiconductor device according to the present invention;

FIG. 3 is a back view showing the one embodiment of the semiconductor device according to the present invention;

FIG. 4 is a circuit diagram illustrating one embodiment of a resonant circuit that uses the semiconductor device according to the present invention;

FIGS. 5A to 5C are manufacturing process sectional views depicting one embodiment of a semiconductor chip according to the present invention;

FIG. 6 is a sectional view showing another embodiment of the semiconductor chip according to the present invention;

FIGS. 7A, 7B1, and 7B2 are manufacturing process sectional views illustrating the one embodiment of the semiconductor chip shown in FIG. 6;

FIG. 8 is a characteristic diagram showing simulation results in the capacitance value of a variable capacitance diode discussed prior to the present invention; and

FIG. 9 is a characteristic diagram illustrating simulation results in the resistance value of the variable capacitance diode discussed prior to the present invention.

### DETAILED DESCRIPTION OF THE PREFERRED EMBODIMENTS

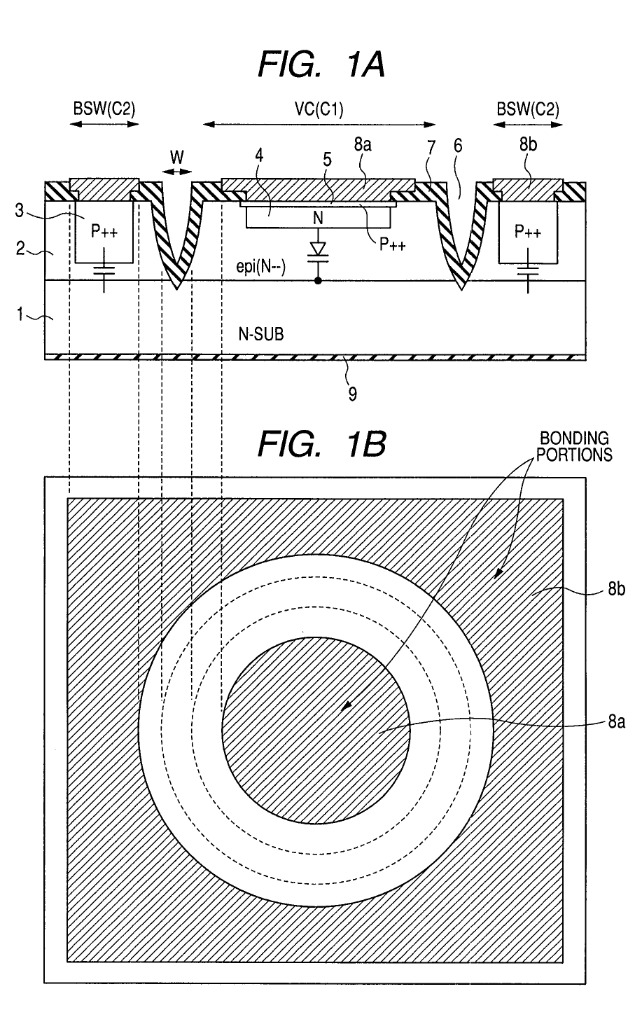

A configuration diagram of one embodiment of a semiconductor chip that configures a variable or programmable filter circuit according to the present invention is shown in FIGS. 1A and 1B Here, the semiconductor chip means a semiconductor device which includes a semiconductor substrate comprising monocrystalline silicon, a semiconductor layer comprising monocrystalline silicon epitaxially grown over the semiconductor substrate, a semiconductor layer formed by implanting an impurity into the semiconductor layer, a metal electrode coupled to the semiconductor layer, an insulating film such as a silicon oxide film for protecting the surface of each of the semiconductor layers, etc.

FIG. 1A shows a sectional portion, and FIG. 1B shows a top surface portion, respectively. In FIG. 1A, an epitaxial layer (epi (N−−): first semiconductor layer) 2 lower in impurity concentration than an N-type semiconductor substrate (N-SUB) 1 that configures the cathode side of a variable capacitance diode VC, is formed in a main surface of the semiconductor substrate. The epitaxial layer (epi (N−−)) 2 is partitioned into a first area corresponding to the variable capacitance diode VC (C1) and a second area corresponding to a capacitor SW (C2) substantially operated as a fixed capacitor by a device isolation area 6 having a trench structure. The device isolation area 6 is mainly formed for the purpose of suppressing a parasitic capacitance added to the variable capacitance diode VC and the transverse spread of a depletion layer at its operation.

Although not restricted in particular, the first area corresponding to the variable capacitance diode VC (C1) is roundly formed at the central part of the semiconductor chip shaped in square as seen in its plane as shown in FIG. 1B. The device isolation area 6 shaped in ring form so as to take in the circular first area is formed. The outside of the ring-shaped device isolation area 6 of the semiconductor chip brought to the square is defined as the second area corresponding to the capacitor SW (C2) used as the substantial fixed capacitor.

A P++ type semiconductor region 3 (fourth semiconductor layer) that configures one electrode side of the capacitor SW (C2) is formed in the epitaxial layer (epi (N−−)) 2 of the second area. The semiconductor region 3 is formed deep to decrease in distance from the main surface of the semiconductor substrate (N-SUB) 1. In other words, the bottom of the P++ type semiconductor region 3 (fourth semiconductor layer) is formed at a position closer to the semiconductor substrate than a low portion of a P++ type semiconductor region 5 (third semiconductor layer) to be described later in such a manner that the thickness of the epitaxial layer (epi (N−−)) 2 interposed between the semiconductor region (P++) 3 and the semiconductor substrate (N-SUB) is formed substantially thin.

Although not restricted in particular, an N type semiconductor region 4 (second semiconductor layer) is formed in the epitaxial layer (epi (N−−)) 2 of the first area. The P++ type semiconductor region 5 (third semiconductor layer) that configures the anode side of the variable capacitance diode VC (C1) is formed in the semiconductor region 4. Thus, the variable capacitance diode VC assumes a PN junction diode in which the P++ type semiconductor region 5 is set as the anode side and the an N type semiconductor region comprising the N type semiconductor region 4, the epitaxial layer (epi (N−−)) 2 and the semiconductor substrate (N-SUB) is set as the cathode side.

The thickness of the epitaxial layer (epi (N−−)) 2 of the variable capacitance diode VC (C1) is made thicker than that of the epitaxial layer (epi (N−−)) 2 of the capacitor SW (C2). The spread of the depletion layer, which changes according to a control voltage, is increased so as to have or obtain a large change in capacitance. The N type semiconductor region 4 acts in such a manner that the spread of the depletion layer at the time that the control voltage is low, is reduced to obtain a large capacitance value, and the spread of the depletion layer at the time that a large control voltage is applied thereto is led in the vertical direction of the epitaxial layer (epi (N−−) 2. That is, the transverse spread of the depletion layer is lowered by the N type semiconductor region 4 to reduce a capacitance value with respect to the control voltage, thereby increasing a change in capacitance.

Reference numeral 7 indicates a protective film formed of a laminated film of a silicon oxide film and a silicon nitride film. The protective film 7 is provided at a surface portion excluding the anode electrodes of the variable capacitance diode VC (C1) and capacitor SW (C2), and electrodes 8a (first electrode) and 8b (second electrode) that configure one electrodes thereof respectively. As shown in FIG. 1B, the electrodes 8a and 8b comprise a metal film such as aluminum. The electrodes 8a and 8b respectively function as bonding portions for coupling bonding wires and are coupled to a first signal terminal and a second signal terminal used as variable capacitive elements (variable filter circuits). A gold (Au) layer 9 (third electrode) is formed on the back surface side of the semiconductor substrate (N-SUB) 1 and configures a cathode electrode 2 (third electrode) commonly coupled to the variable capacitance diode VC (C1) and capacitor SW (C2). By die-bonding such a semiconductor chip to metal leads comprising plate-like lead frames or the like, the semiconductor chip is coupled to leads used as voltage control terminals of the variable capacitive elements.

Although not restricted in particular, the semiconductor substrate 1 is set to an arsenic (As) concentration that ranges from about 1×E19 to 1×E20. The epitaxial layer (epi (N−−)) 2 is set to a phosphorus (P) concentration that ranges from about 1×E15 to 1×E16. The N type semiconductor region 4 is set to a phosphorus concentration that ranges from about 1×E17 to 1×E18. The P++ type semiconductor region 5 is set to a boron (B) concentration that ranges from about 1×E19 to 1×E20. The P++ type semiconductor region 3 is set to a boron (B) concentration that ranges from about 1×E19 to 1×E20.

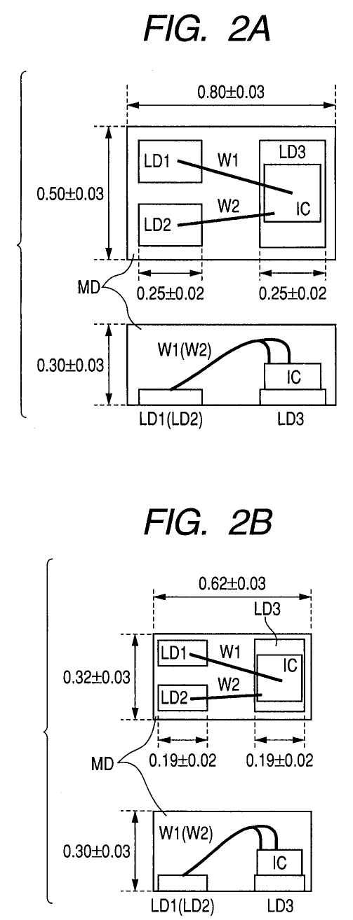

A configuration diagram of a semiconductor device (resin molded type semiconductor package) according to the present invention is shown in FIGS. 2A and 2B. Sectional and planar forms of two types of semiconductor devices are shown in the same figure. Each of semiconductor chips IC has a back electrode (third electrode) thereof die-bonded to a lead LD3 so as to contact the surface side of the lead LD3. A central par of the semiconductor chip and a lead LD1 are coupled to each other by a bonding wire W1 such as gold. A peripheral portion of the semiconductor chip and a lead LD2 are coupled to each other by a bonding wire W2. A bonding portion lying in the central part of the semiconductor chip corresponds to the anode electrode of the variable capacitance diode VC (C1). A bonding portion located at the peripheral portion of the semiconductor chip corresponds to one electrode of the capacitor SW (C2). The semiconductor chip IC and the bonding wires W1 and W2 are sealed with, for example, a resin molded body MD such as an epoxy resin. The back surface sides of the leads LD1 through LD3 are exposed and used as surface-mounting external electrodes respectively.

FIG. 2A is a type called “0805”, which has plane dimensions set to about 0.8 mm×0.5 mm and a thickness set to about 0.3 mm. FIG. 2B is a type called “0603”, which has plane dimensions set to about 0.6 mm×0.3 mm and a thickness set to about 0.3 mm in a manner similar to the above.

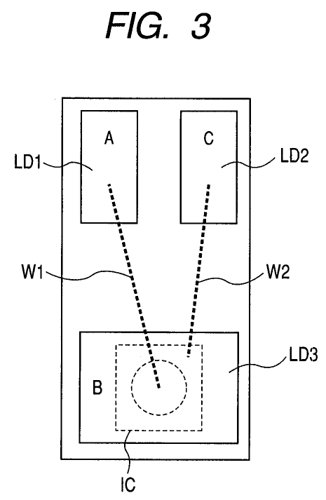

A back view of the semiconductor device according to the present invention is shown in FIG. 3. The back surface side of the semiconductor device has a first terminal A corresponding to the lead LD1, a second terminal C corresponding to the second lead LD2 and a third terminal B corresponding to the third lead LD3. As indicated by dotted lines in the same figure, such a semiconductor chip IC and bonding wires W1 and W2 as described above are provided inside the semiconductor device and electrically coupled to the leads LD1 and LD2. The semiconductor chip IC is die-bonded to the third lead LD3 thereby to couple the semiconductor substrate of the semiconductor chip and the cathode electrode shared at its back surface to the lead LD3.

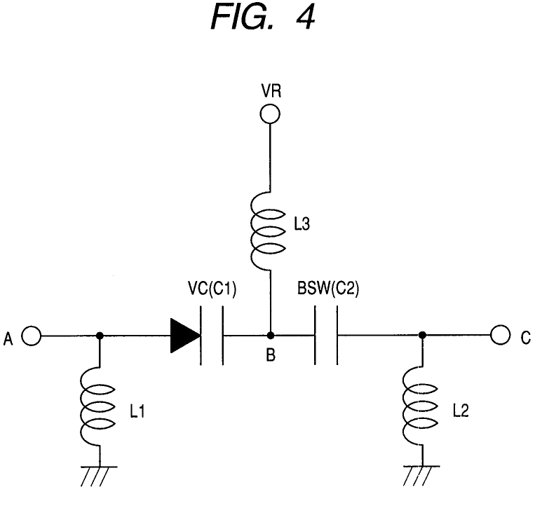

A circuit diagram of one embodiment of a resonant circuit (variable or programmable filter circuit) that uses the semiconductor device according to the present invention is shown in FIG. 4. Inductances L1 and L2 that configure the resonant circuit are respectively coupled between terminals A and C of the semiconductor device and a ground potential point of the circuit. An anode electrode of a variable capacitance diode VC (C1) formed in the semiconductor chip is coupled to the terminal A. One electrode of a capacitor SW (C2) formed in the semiconductor chip is coupled to the terminal C. A control voltage VR is supplied via an inductance L3 to a terminal B used as a control voltage terminal corresponding to a cathode electrode (electrode on the other side of capacitor SW) coupled in common between the variable capacitance diode VC (C1) and the capacitor SW (C2). The inductance L3 is set so as to have impedance high with respect to a resonant frequency. That is, the inductance L3 supplies the control voltage VR to the variable capacitance diode VC (C1) on a dc basis and is brought to high impedance on an ac basis. Thus, the inductance L3 can be replaced with a high resistive element.

The semiconductor device according to the present embodiment comprises a series circuit of the variable capacitance diode VC and the capacitor SW. Therefore, assuming that their capacitance values are C1 and C2, a combined capacitance C thereof can be reduced like 1/C1+1/C2. In the case of the capacitor SW as described above, depi of the above equation (1) can be significantly reduced as compared with depi of the variable capacitance diode VC if the P++ layer is formed deep as one electrode side of the capacitor and the thickness of the epitaxial layer (epi (N−−)) 2 that configures the PN junction is substantially reduced. Thus, since an equivalent resistance value can be left held at an equivalent resistance value of a substantially one variable capacitance diode VC while each capacitance value is being reduced by the series circuit, a low Ct and a low Rs can be realized.

Since the capacitor SW is also of a PN junction capacitance or capacitor, strictly speaking, the capacitance value at the PN junction portion changes minimally in response to the control voltage VR in a manner similar to the variable capacitance diode VC. Since, however, the small amount of change in the capacitance of the capacitor SW is very smaller than the amount of change in the capacitance of the variable capacitance diode VC, it can be assumed to be a fixed capacitance. That is, since a change in the capacitance C1 of the variable capacitance diode VC exerts control over a change in the combined capacitance in view of the combined capacitance C (1/C1+1/C2), the capacitance C2 of the capacitor SW can be substantially set as a fixed capacitance.

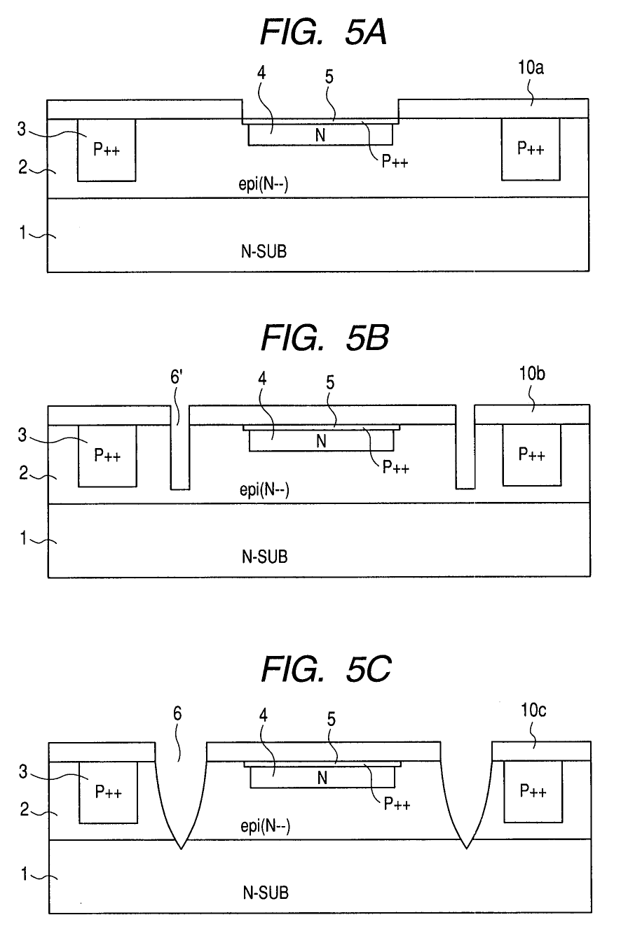

A manufacturing process sectional view of one embodiment of a semiconductor chip according to the present invention is shown in FIGS. 5A to 5C. Although the present embodiment merely illustrates one semiconductor chip to make it easy to see the figure, similar semiconductor chips are actually formed over a known semiconductor wafer in plural form. The semiconductor wafer is divided into individual semiconductor chips by dicing in a final process. In FIG. 5A, an epitaxial layer epi used as an N−− type 2 is grown over an N-type semiconductor substrate 1. A photoresist film is formed on the surface corresponding to the capacitor SW, of the epitaxial layer epi and boron is implanted and thermally diffused therein to inject B (boron) into the epitaxial layer epi. Then, heat treatment is applied thereto in a nitrogen atmosphere to perform annealing, thereby forming a P++ type semiconductor layer 3 set to a deep depth. Further, a photoresist film is formed in the surface corresponding to a variable capacitance diode VC and phosphor is implanted therein and thermally diffused therein thereby to form an N type semiconductor layer 4. Thereafter, a photoresist film 10a is formed as shown in the same figure and the above boron is implanted and thermally diffused therein thereby to form a P++ type semiconductor layer 5. By forming a photoresist film over the entire surface and performing selective etching thereon, the respective photoresist films referred to above are patterned to form the respective semiconductor regions such as described above.

In FIG. 5B, a silicon oxide film is deposited over the whole main surface of a semiconductor substrate by high-temperature and low-pressure CVD, and a photoresist is formed over the full surface of the silicon oxide film. The photoresist is subjected to exposure and development, followed by being patterned into a resist mask with a circular opening provided at a central part of a predetermined trench 6 forming area. Then, the silicon oxide film is removed by dry etching using this resist mask to expose the epitaxial layer epi. An intermediate trench 6′ is formed in the epitaxial layer epi by anisotropic etching using the above resist mask and silicon oxide film lob as masks.

In FIG. 5C, a cleaning process is performed after execution of ashing using ozone to remove the resist mask 10b, after which a photoresist is formed over the entire surface. The photoresist is subjected to exposure and development, followed by being patterned into a resist mask with a circular opening provided in the predetermined trench 6 forming area. Then, the silicon oxide film is removed by wet etching using this resist mask to expose the epitaxial layer epi and the intermediate layer 6′. An open region of the resist mask used in the wet etching is larger than that of the resist mask 10b employed in the dry etching. With a resist mask and a silicon oxide film 10c as masks, parts of the epitaxial layer epi and the N-type semiconductor substrate 1 are etched deeper than the intermediate trench 6′ from the bottom face of the intermediate trench 6′ by dry etching using isotropic gas. Upon the anisotropic etching, the etching proceeds from the main surface of the semiconductor substrate 1 and the side and bottom faces of the intermediate trench 6′, respectively, which are exposed from the resist mask 10c. Therefore, the sectional shape of the trench 6 comprises a surface layer portion continuous from the main surface of the semiconductor substrate, an intermediate portion continuous in connection with the surface layer portion, and a deep layer portion continuous from the intermediate portion. Sidewalls of the surface layer portion, intermediate portion and deep layer portion are respectively shaped in a forward tapered form whose upper portion is broader in width than its lower portion.

The rate of flow of etching gas at dry etching and the time taken for etching are adjusted to bring the trench 6 into the forward tapered form whose lower portion is more thinner than its upper portion in trench's sectional shape. Although not shown in the figure, ashing using ozone is performed to remove the resist mask 10c and the silicon oxide film is removed by wet etching. Subsequently, a protective film 7 comprising a laminated film formed by laminating a PSG (Phospho Silicate Glass) film based on CVD, a plasma silicon nitride film and the like over a silicon oxide film based on thermal oxidation used as a protection insulating film, for example, is formed over the full main surface of the semiconductor substrate including the inside of the trench 6. A resist mask with coupling regions of electrodes 8a and 8b being made open is formed with respect to the protective film 7 by photolithography. It is selectively removed by dry etching using the resist mask to perform patterning of the protection insulating film 7, whereby the P++ semiconductor layers 3 and 5 of the main surface of the semiconductor substrate, which assume the connecting areas, are exposed. After the resist mask for opening has been removed, a metal film using aluminum containing silicon therein is deposited over the entire main surface of the semiconductor substrate by sputter or the like. A resist mask, which covers the forming areas of the electrodes 8a and 8b, is formed by photolithography. The metal film is selectively removed by dry etching using the resist mask to perform patterning thereof, thereby forming the corresponding electrodes 8a and 8b.

After the electrode forming resist mask has been removed, the back surface placed on the side opposite to the main surface of the semiconductor substrate is subjected to grinding processing to make the thickness of the semiconductor substrate thin. Then, a metal film including laminated Au (gold), for example is deposited over the semiconductor substrate 1 having the back surface by evaporation or the like. The metal film is wet-etched to form a cathode electrode 9 used as the control voltage terminal shown in FIGS. 1A and 1B.

In the present embodiment, the sidewalls of the surface layer portion, intermediate portion and deep layer portion of the trench 6 are respectively brought to the forward tapered form whose upper portion is broader in width than the lower portion, thereby making it possible to deposit the protection insulting film 7 on the sidewalls and bottom face of the trench 6 stably. Thus, since the protection insulating film 7 formed inside the trench 6 can be formed to a sufficient thickness, it is possible to suppress the shortage of the thickness of the protection insulating film 7.

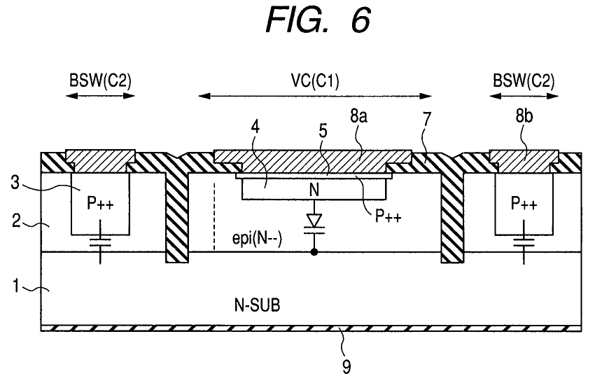

FIG. 6 shows a sectional view of another embodiment of the semiconductor chip according to the present invention. In the present embodiment, a protective film 7 is embedded in a trench used as a device isolation area and hence the protective film is configured as the device isolation area. Therefore, the trench in which the protective film is embedded reaches a main surface portion of a semiconductor substrate 1 through the epitaxial layer epi 2. The present embodiment is similar to the embodiment shown in FIGS. 1A and 1B in other configuration.

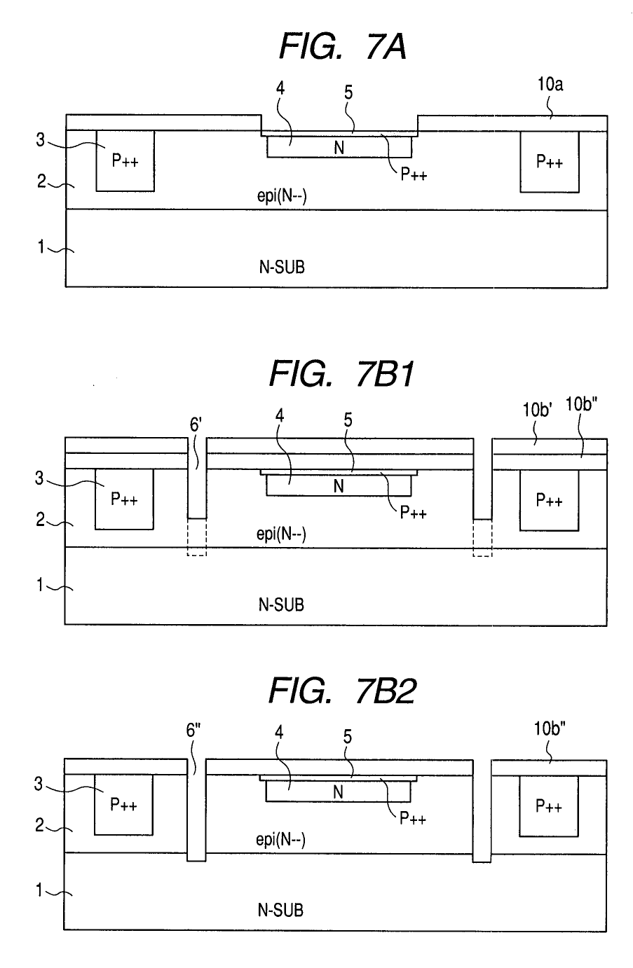

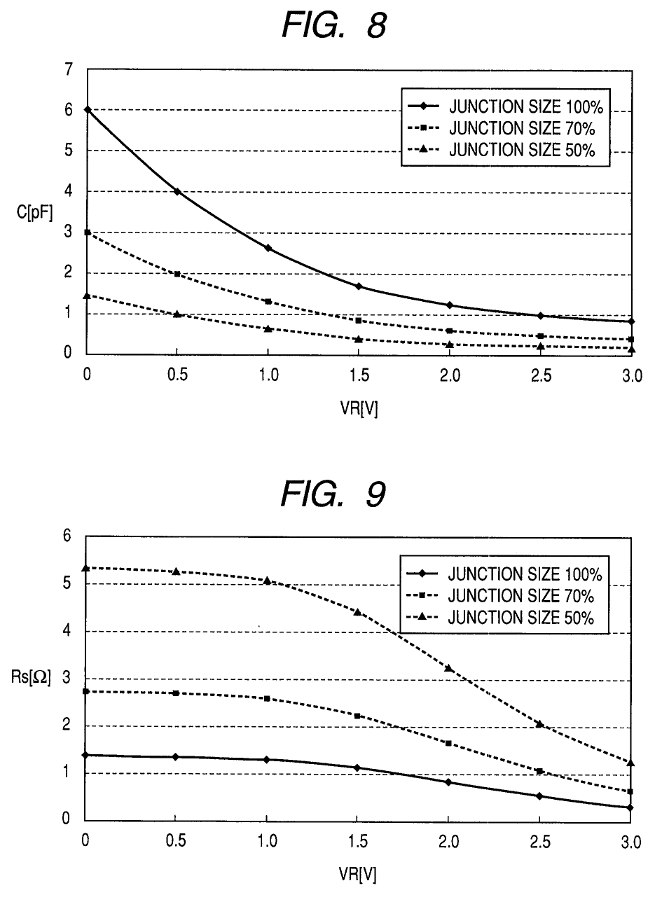

A manufacturing process sectional view of one embodiment of the semiconductor chip shown in FIG. 6 is shown in FIGS. 7A, 7B1, and 7B2. FIGS. 7A and 7B1 are similar to FIGS. 5A and 5C. FIG. 7B1 however shows that an intermediate trench 6′ that reaches an N−− type (or I-type semiconductor layer) 2 is formed by performing isotropic dry etching using a resist mask 10b′ and a silicon oxide film 10b″ equivalent to the mask 10b of FIGS. 5A to 5C.

In FIG. 7B2, the photoresist film 10b′ is removed and second time etching is performed with the silicon oxide film 10b″ as a mask. Upon the second time etching, a trench 6″ having such a depth as to extend through the epitaxial layer epi (I-type semiconductor layer) 2 and reach the semiconductor substrate 1 is provided. Thereafter, a stacked film obtained by stacking a PSG (Phospho Silicate Glass) film based on CVD, a plasma silicon nitride film and the like over, for example, a silicon oxide film based on thermal oxidation used as a protection insulating film inclusive of the trench 6″ is formed and embedded into the trench 6″. Subsequently, such electrodes 8a, 8b and 9 as described above are formed.

While the invention made above by the present inventors has been described specifically on the basis of the preferred embodiments, the present invention is not limited to the embodiments referred to above. Various changes can be made thereto without the scope not departing from the gist thereof. The impurity concentration of each semiconductor layer can adopt various embodiments in such a manner that the semiconductor substrate is set as an N+ type, for example. The conductivity type is reversed and the electrode having the substantial fixed capacitance may be shared with the variable capacitance diode to provide a series form. Such a form that the N type semiconductor layer 4 of the variable capacitance diode VC is omitted and the sidewalls of the trench contact the PN junction may be adopted. Any one may be adopted if the device isolation area can be partitioned into the two areas as described above. The present invention can widely be utilized as a low-capacitance and low-resistance variable capacitance diode.

1. A semiconductor device for configuring a variable filter circuit, comprising:
a semiconductor substrate of a first conductivity type;
a first semiconductor layer of the first conductivity type formed over the semiconductor substrate and having an impurity concentration lower than the semiconductor substrate;
a second semiconductor layer of the first conductivity type formed in a first area of a main surface of the first semiconductor layer and having an impurity concentration higher than the first semiconductor layer;
a third semiconductor layer formed in a surface of the second semiconductor layer and having a second conductivity type opposite to the first conductivity type;
a first electrode formed over the third semiconductor layer and electrically coupled to the third semiconductor layer;
a fourth semiconductor layer having the second conductivity type formed in a second area of the main surface of the first semiconductor layer, which is different from the first area;
a second electrode formed over the fourth semiconductor layer and electrically coupled to the fourth semiconductor layer; and
a third electrode formed at a back surface of the semiconductor substrate and electrically coupled to the semiconductor substrate,
wherein a diode element including a PN junction formed by the second semiconductor layer and the third semiconductor layer is formed,
wherein a capacitive element including the first semiconductor layer, the semiconductor substrate and the fourth semiconductor layer in the second area is formed,
wherein the third electrode is coupled to a control voltage terminal, wherein the first and second electrodes are respectively coupled to a first signal terminal and a second signal terminal, and
wherein the capacitance of the diode element is controlled by a voltage applied to the control voltage terminal.

2. The semiconductor device according to claim 1,
wherein the semiconductor substrate and the first semiconductor layer are respectively shaped in the form of a square as seen on a plane,
wherein the first area is provided at a central part of the first semiconductor layer, and
wherein the second area is formed in the first semiconductor layer and provided on the peripheral side of the first semiconductor layer so as to surround the first area with a device isolation area defining the first and second areas being interposed therebetween.

3. The semiconductor device according to claim 2, wherein the first area is shaped in circular form.

4. The semiconductor device according to claim 3, wherein the device isolation area has a trench structure.

5. The semiconductor device according to claim 3, wherein the device isolation area comprises a trench that extends through the first semiconductor layer and reaches a main surface of the semiconductor substrate, and an insulator embedded in the trench.

6. The semiconductor device according to claim 4, wherein a bottom portion of the fourth semiconductor layer is formed at a position closer to the semiconductor substrate than a low portion of the third semiconductor layer.

7. The semiconductor device according to claim 6, further including a resin-molded body which seals a first lead, a second lead and a third lead comprising plate-shaped lead frames, respective parts of the first, second and third leads, and a semiconductor chip including the semiconductor substrate and the first semiconductor layer,
wherein the first electrode and the first lead are coupled by a first bonding wire,
wherein the second electrode and the second lead are coupled by a second bonding wire, and
wherein the semiconductor chip is die-bonded to a main surface of the third lead.

8. The semiconductor device according to claim 1, wherein the diode element is a variable capacitance diode.

9. The semiconductor device according to claim 8, wherein the capacitive element is coupled to the variable capacitance diode via the semiconductor substrate and coupled in series with a signal path extending via the first and second signal terminals.
